(19) United States
(12) Patent Application Publication
(10) Pub. No.: US 2016/0128146 A1
(43) Pub. Date: May 5, 2016

(54) CURRENT-STEERING DAC CIRCUIT AND LED CIRCUIT USING THE SAME

(71) Applicant: PIXART IMAGING INC., Hsin-Chu (TW)

(72) Inventors: CHIA-HSUN WU, HSIN-CHU (TW); PENG-SHENG CHEN, HSIN-CHU (TW); HSIANG-WEI HWANG, HSIN-CHU (TW); JUI-TE CHIU, HSIN-CHU (TW)

(21) Appl. No.: 14/635,740

(22) Filed: Mar. 2, 2015

(30) Foreign Application Priority Data
Nov. 5, 2014 (TW) 103138384

(51) Int. Cl. H05B 33/08; H03M 1/66

(52) U.S. Cl. CPC H05B 33/0815; H03M 1/66; H05B 33/0845

(57) ABSTRACT

A current-steering DAC circuit for switching a light emitting diode, the current-steering DAC circuit including a current-steering DAC and a resistor. The current-steering DAC outputs a stable current and includes a plurality of current-steering units with a first output end and a second output end. The first output end is electrically connected to the light emitting diode, and the second output end is electrically connected to the resistor. Each of the current-steering units includes a current source and a switching circuit. A first end of the switching circuit is electrically connected to the current source. A second end and a third end of the switching circuit are electrically connected to the first output end and the second output end of the current-steering DAC, respectively. The switching circuit is controlled by a switching signal so as to selectively connect one of the second end and the third end to the first end.

### BACKGROUND

1. Technical Field

The present invention generally relates to a light emitting diode (LED) circuit and, more particularly, to a current-steering digital-to-analog converter (DAC) circuit for switching an LED and an LED circuit using the current-steering DAC circuit.

2. Description of Related Art

On the awakening of environmental protection and energy-saving, the LED industry has grown because LED lighting has been widely used to replace conventional lighting due to the advantages such as energy efficiency and expected lifetime.

More particularly, the brightness of an LED depends on the current flowing through the LED. It is crucial, when driving an LED, to control the current flowing through the LED to reach the designed current rating and to be stable and unaffected by the driving voltage, the temperature, and so on. As a result, the LED outputs light with expected brightness and is prevented from being damaged. Furthermore, the LED is alternate current (AC) driven and the current through the LED varies exponentially with the applied forward-bias voltage. Therefore, a minimal voltage variation may result in a large variation of current through the LED, which causes brightness instability or failure when being overpowered.

On the other hand, the conventional LED circuit may not rapidly change the current through the LED, which limits the on/off speed of the LED. As a result, the conventional LED driving circuit may be used with one or more current-steering DACs to precisely control the current. With the use of the current-steering DACs, the LED circuit provides fast switching of the current-steering units in the current-steering DAC so as to rapidly adjust the current through the LED. However, when at least one of the current-steering units of the current-steering DAC is switched off, the forward-bias voltage of the current-steering DAC varies. The forward-bias voltage is re-built and reaches the previous rating after the switched off current-steering unit is switched on again.

With reference to FIG. 1, FIG. 1 is a schematic circuit diagram of a conventional current-steering DAC for a light emitting diode circuit. The current-steering DAC 10 is electrically connected to the LED L1 at the output and provides the LED L1 with a stable current. Moreover, the current-steering DAC 10 includes a plurality of current-steering units 11. Each of the current-steering units 11 receives a switching signal TS and a switching circuit SW1 of the current-steering unit 11 is switched on/off by the switching signal TS. More particularly, the number of the current-steering units 11 corresponds to the number of control bits with respect to switch and brightness control. Each switching signal TS corresponds to one of the control bits.

When the switching circuit SW1 of at least one of the current-steering units 11 is switched on, the current-steering DAC 10 outputs a current through the LED L1 to drive the LED L1 and build a forward-bias voltage. On the contrary, the switching circuits SW1 of all the current-steering units 11 have to be switched off to prevent the current-steering DAC 10 from outputting a current through the LED L1. However, this may cause a variation of the forward-bias voltage. Moreover, when the brightness of the LED L1 is to be adjusted, at least one of the current-steering units 11 has to be switched off This may also cause a variation of the forward-bias voltage. The forward-bias voltage is re-built and reaches the previous rating after the switched off current-steering unit 11 is switched on again. It takes a period of time to re-build the forward-bias voltage, which results in imprecision of brightness during the period of time.

Simply put, since the conventional current-steering DAC is affected by the switching of the LED as well as the switching circuit, it fails to rapidly provide the LED with a current with a precise rating so that the LED cannot rapidly provide light with expected brightness.

### SUMMARY

One embodiment of the present invention provides a current-steering DAC circuit for switching a diode. The current-steering DAC circuit includes a current-steering DAC and a resistor. The current-steering DAC outputs a stable current and is provided with a first output end and a second output end. The first output end is electrically connected to the light emitting diode. The second output end is electrically connected to the resistor. Moreover, the current-steering DAC includes a plurality of current-steering units. Each of the current-steering units includes a current source and a switching circuit. The first end of the switching circuit is electrically connected to the current source, and the second end and the third end of the switching circuit are electrically connected to the first output end and the second output end of the current-steering DAC, respectively. The switching circuit is controlled by a switching signal to selectively connect one of the second end and the third end to the first end.

One embodiment of the present invention further provides a light emitting diode (LED) circuit. The LED circuit includes a light emitting diode, and a current-steering DAC circuit for switching the light emitting diode. The current-steering DAC circuit includes a current-steering DAC and a resistor. The current-steering DAC outputs a stable current and is provided with a first output end and a second output end. The first output end is electrically connected to the light emitting diode. The second output end is electrically connected to the resistor. Moreover, the current-steering DAC includes a plurality of current-steering units. Each of the current-steering units includes a current source and a switching circuit. The first end of the switching circuit is electrically connected to the current source, and the second end and the third end of the switching circuit are electrically connected to the first output end and the second output end of the current-steering DAC, respectively. The switching circuit is controlled by a switching signal to selectively connect one of the second end and the third end to the first end.

Accordingly, one embodiment of the present invention provides a current-steering DAC circuit and an LED using the current-steering DAC circuit. An additional current path is provided to simulate the operation of a differential pair so that the simulated differential pair provides a current through the LED without re-building the forward-bias voltage across the current-steering DAC circuit and the LED to achieve rapid switching of the LED and precise control of the brightness.

In order to further understand the techniques, means and effects of the present disclosure, the following detailed descriptions and appended drawings are hereby referred to, such that, and through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a schematic circuit diagram of a conventional current-steering DAC for a light emitting diode circuit;

FIG. 2 is a schematic circuit diagram of a current-steering DAC according to one embodiment of the present invention;

FIG. 3 is a schematic circuit diagram of a current-steering DAC according to another embodiment of the present invention; and

FIG. 4 is a schematic circuit diagram of a light emitting diode circuit according to one embodiment of the present invention.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

With reference to FIG. 2, FIG. 2 is a schematic circuit diagram of a current-steering DAC according to one embodiment of the present invention. The current-steering DAC circuit 2 switches a diode as well as the switching circuit SW2. For example, the diode can be an LED L2, which the present invention is not limited to. The current-steering DAC circuit 2 may include a current-steering DAC 20 and a resistor R1. The current-steering DAC 20 outputs a stable current and is provided with a first output end P and a second output end Q. The first output end P is electrically connected to the LED L2, while the second output end Q is electrically connected to the resistor R1.

Moreover, the current-steering DAC 20 may include a plurality of current-steering units 21. Each of the current-steering units 21 includes a current source I1 and a switching circuit SW2. The first end of the switching circuit SW2 is electrically connected to the current source I1. The second end and the third end of the switching circuit SW2 are electrically connected to the first output end P and the second output end Q of the current-steering DAC 20, respectively. The switching circuit SW2 is controlled by the switching signal Din to selectively connect one of the second end and the third end to the first end. The switching signal Din is, for example, one of the control bits with respect to switch and brightness control of the LED L2.

In other words, the switching signal Din controls the current from the current-steering units 21 of the current-steering DAC 20 through the first output end P or the second output end Q. It should be noted that, the present invention is not limited by the number and implementations of the current-steering units 21 of the current-steering DAC 20. The person with ordinary skill in the art may make modifications on the current-steering units 21 within the scope of the present invention.

Therefore, when the second end and the first end of the switching circuit SW2 of at least one of the current-steering units 21 are connected, at least one of the current-steering units 21 of the current-steering DAC 20 outputs a current switched to the first output end P. In other words, at least one of the current-steering units 21 of the current-steering DAC 20 outputs a current through the LED L2 to drive the LED L2 to emit light.

On the contrary, when the switching circuit SW2 of at least one of the current-steering units 21 is switched to connect the third end and the first end, at least one of the current-steering units 21 of the current-steering DAC 20 outputs a current switched to the second output end Q. In other words, at least one of the current-steering units 21 of the current-steering DAC 20 outputs a current through the resistor R1, instead of the LED L2, to lower the brightness of the LED L2. When the third ends and the first ends of the switching circuits SW2 of all the current-steering units 21 are connected, the LED L2 is switched off and does not emit light.

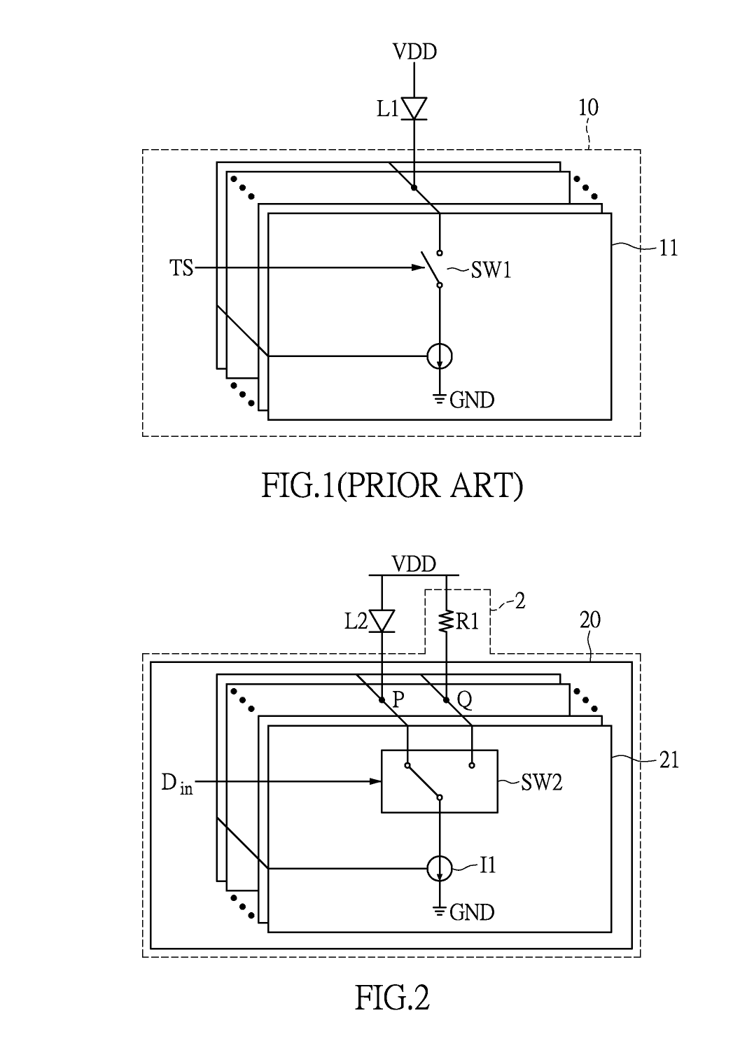

Accordingly, compared to the conventional current-steering DAC 10 as shown in FIG. 1, the current-steering DAC circuit 2 according to one embodiment of the present invention is provided with an additional current path to simulate the operation of a differential pair so that the current-steering units 21 of the current-steering DAC 20 provide a current from the simulated differential pair. Accordingly, with the resistor R1 properly determined, the voltage at the first output end P when the LED L2 is switched on (i.e., the first end is connected to the second end of the switching circuit SW2 of each of the current-steering units 21) is equal to the voltage at the second output end Q when the LED L2 is switched off (i.e., the first end is connected to the third end of the switching circuit SW2 of each of the current-steering units 21). In a broad sense, the variation between the forward-bias voltage of the current-steering units 21 before the first end and the third end of the switching circuit SW2 are connected and the forward-bias voltage of the current-steering units 21 after the first end and the third end of the switching circuit SW2 are connected is small. In other words, the forward-bias voltage of the current-steering units 21 remains stable. Therefore, the forward-bias voltage does not have to be re-built after the first end and the second end of the switching circuit SW2 are connected again. As a result, the LED L2 immediately outputs light with expected brightness.

The present invention is not limited to the implementations of the resistor R1. Therefore, the forward-bias voltage across the current-steering DAC 20 according to one embodiment of the present invention is not affected by the switching of the LED L2 and the variation of the current from the current-steering DAC 20 and does not have to be re-built. In other words, the current-steering DAC 20 according to one embodiment of the present invention may rapidly provide a current with expected current rating and drive the LED L2 to emit light with expected brightness.

On the other hand, as previously stated, in one embodiment of the present invention, one end of the LED L2 and one end of the resistor R1 are electrically connected to the first output end P and the second output end Q of the current-steering DAC 20. However, in one embodiment of the present invention, another end of the LED L2 and another end of the resistor R1 may be electrically connected to the system voltage VDD. Therefore, the person with ordinary skill in the art may make modifications on electrical connections to the system voltage VDD within the scope of the invention.

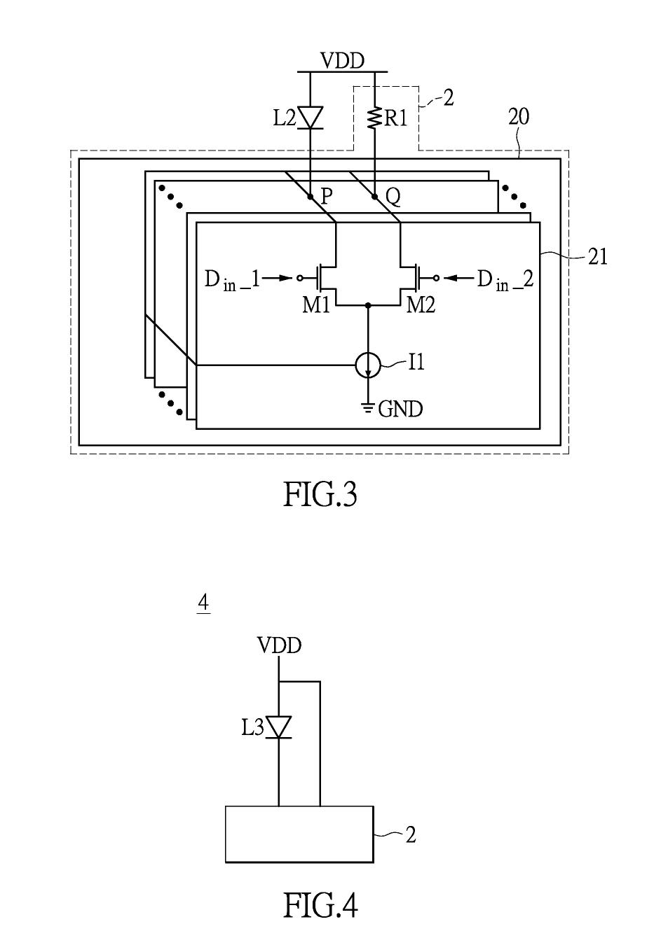

Afterwards, to further describe the detailed implementations of the switching circuit SW2 of the current-steering DAC 20, the present invention further provides an example of the switching circuit SW2. With reference to FIG. 3, FIG. 3 is a schematic circuit diagram of a current-steering DAC according to another embodiment of the present invention. However, the description of the switching circuit SW2 of the current-steering DAC 20 only illustrates an example and never intends to limit the present invention. The switching circuit SW2 of the present embodiment can be used with the current-steering DAC circuit 2 as shown in FIG. 2. With reference to FIG. 2 and FIG. 3, the same reference numbers are used in the drawings and the description to refer to the same or like parts.

More particularly, the switching circuit SW2 may include a first transistor M1 and a second transistor M2. The drain of the first transistor M1 and the drain of the second transistor M2 are electrically connected to the second end and the third end of the switching circuit SW2, respectively. The source of the first transistor M1 and the source of the second transistor M2 are electrically connected to the first end of the switching circuit SW2. Moreover, the gate of the first transistor M1 and the gate of the second transistor M2 receive the switching signal Din.

As previously stated, since the switching circuit SW2 is controlled by the switching signal Din to selectively connect one of the second end and the third end to the first end. In other words, the current only flows through the first transistor M1 when the second end and the first end of the switching circuit SW2 are connected, and the current only flows through the second transistor M2 when the third end and the first end of the switching circuit SW2 are connected. Accordingly, the first transistor Ml and the second transistor M2 can be complementary.

Accordingly, the light emitting diode switching signal Din may further include a first control signal Din_1 and a second control signal Din_2. The second control signal Din_2 may be a reverse signal of the first control signal Din_1. The gate of the first transistor M1 receives the first control signal Din_1 and the gate of the second transistor M2 receives the second control signal Din_2. Therefore, when the first transistor M1 is controlled by the first control signal Din_1 so that the second end and the first end of the switching circuit SW2 are connected, the second transistor M2 is also controlled by the second control signal Din_2 so that the third end and the first end of the switching circuit SW2 are not connected. On the contrary, when the first transistor M1 is controlled by the first control signal Din_1 so that the second end and the first end of the switching circuit SW2 are not connected, the second transistor M2 is also controlled by the second control signal Din_2 so that the third end and the first end of the switching circuit SW2 are connected. In other words, the first transistor M1 and the second transistor M2 are respectively controlled by the first control signal Din_1 and the second control signal Din_2 to selectively conduct the current from the current-steering DAC 20 to the first output end P or the second output end Q.

As previously stated, in one embodiment of the present invention, the current-steering DAC circuit 2 is provided with an additional current path to selectively conduct the current from the current-steering units 21 of the current-steering DAC 20 so that the voltage at the first output end P when the LED L2 is switched on is equal to the voltage at the second output end Q when the LED L2 is switched off. In other words, the variation between the forward-bias voltage of the current-steering units 21 before the current from the current-steering DAC 20 changes and the forward-bias voltage of the current-steering units 21 after the current from the current-steering DAC 20 changes is small. Substantially, the forward-bias voltage of the current-steering units 21 remains stable. Therefore, in one embodiment of the present invention, the forward-bias voltage of the current-steering DAC 20 does not have to be re-built due to the switching of the LED L2 as well as the changes in the current from the current-steering DAC 2. As a result, the current-steering DAC 20 rapidly provides a current with a precise rating so that the LED L2 immediately outputs light with expected brightness.

As previously stated, the current-steering DAC circuit 2 switches the LED L2. To further describe the detailed implementations of the current-steering DAC circuit 2, the present invention further provides an example of the LED circuit. With reference to FIG. 4, FIG. 4 is a schematic circuit diagram of a light emitting diode circuit according to one embodiment of the present invention. The LED circuit 4 of the present embodiment includes the current-steering DAC circuit 2 as shown in FIG. 2. With reference to FIG. 2 and FIG. 4, the same reference numbers are used in the drawings and the description to refer to the same or like parts.

With reference to FIG. 2 and FIG. 4, the LED circuit 4 according to one embodiment of the present invention includes an LED L3 and a current-steering DAC circuit 2 as shown in FIG. 2. The current-steering DAC circuit 2 switches the LED L3. The current-steering DAC circuit 2 includes a current-steering DAC 20 and a resistor R1. The current-steering DAC 20 outputs a stable current and is provided with a first output end P and a second output end Q. The first output end P is electrically connected to the LED L3, while the second output end Q is electrically connected to the resistor R1.

Moreover, the current-steering DAC 20 may include a plurality of current-steering units 21. Each of the current-steering units includes a current source I1 and a switching circuit SW2. The first end of the switching circuit SW2 is electrically connected to the current source I1. The second end and the third end of the switching circuit SW2 are electrically connected to the first output end P and the second output end Q of the current-steering DAC 20, respectively. The switching circuit SW2 is controlled by the switching signal Din to selectively connect one of the second end and the third end to the first end.

In addition, in one embodiment of the present invention, one end of the LED L3 and one end of the resistor R1 are electrically connected to the first output end P and the second output end Q of the current-steering DAC 20. However, in one embodiment of the present invention, another end of the LED L3 and another end of the resistor R1 may be electrically connected to the system voltage VDD.

On the other hand, in one embodiment of the present invention, the current-steering DAC circuit 2 of the LED circuit 4 may include a switching circuit SW2 as shown in FIG. 3. Since the switching circuit SW2 has been previously described, descriptions thereof are thus not redundantly repeated.

As stated above, one embodiment of the present invention provides a current-steering DAC circuit and an LED circuit using the current-steering DAC circuit. An additional current path is provided to simulate the operation of a differential pair so that the simulated differential pair provides a current through the LED without re-building the forward-bias voltage across the current-steering DAC circuit and the LED to achieve rapid switching of the LED and precise control of the brightness.

The above-mentioned descriptions represent merely the exemplary embodiment of the present disclosure, without any intention to limit the scope of the present disclosure thereto. Various equivalent changes, alterations or modifications based on the claims of present disclosure are all consequently viewed as being embraced by the scope of the present disclosure.

What is claimed is:

1. A current-steering digital-to-analog converter (DAC) circuit for switching a diode, said current-steering DAC circuit comprising:
a current-steering DAC for outputting a stable current, said current-steering DAC being provided with a first output end and a second output end, wherein said first output end is electrically connected to said diode; and
a resistor being electrically connected to said second output end of said current-steering DAC;
wherein said current-steering DAC comprises:
a plurality of current-steering units, each of the said current-steering units comprising a current source and a switching circuit, wherein a first end of said switching circuit is electrically connected to said current source, a second end and a third end of said switching circuit are electrically connected to said first output end and said second output end, respectively, and said switching circuit is controlled by a switching signal to selectively connect one of said second end and said third end to said first end.

2. The current-steering DAC circuit of claim 1, wherein said diode is a light emitting diode.

3. The current-steering DAC circuit of claim 1, wherein a voltage at said first output end when said first end is connected to said second end of said switching circuit of each of said current-steering units is equal to a voltage at said second output end when said first end is connected to said third end of said switching circuit of each of said current-steering units.

4. The current-steering DAC circuit of claim 1, wherein said current-steering DAC outputs said stable current to said diode when said second end of said switching circuit of each of said current-steering units is connected to said first end of said switching circuit of each of said current-steering units.

5. The current-steering DAC circuit of claim 1, wherein said current-steering DAC outputs said stable current to said resistor when said third end of said switching circuit of each of said current-steering units is connected to said first end of said switching circuit of each of said current-steering units.

6. The current-steering DAC circuit of claim 1, wherein one end of said resistor and one end of said diode are electrically connected to a system voltage, and the other end of said diode and the other end of said resistor are electrically connected to said first output end and said second output end, respectively.

7. The current-steering DAC circuit of claim 1, wherein said switching signal comprises a first control signal and a second control signal, said second control signal is a reverse signal of said first control signal, said switching circuit comprises a first transistor and a second transistor, a drain of said first transistor and a drain of said second transistor are electrically connected to said second end and said third end, respectively, a source of said first transistor and a source of said second transistor are electrically connected to said first end, and a gate of said first transistor and a gate of said second transistor receive said first control signal and said second control signal, respectively.

8. A light emitting diode (LED) circuit, comprising:
a light emitting diode; and
a current-steering DAC circuit for switching said light emitting diode, said current-steering DAC circuit comprising:
a current-steering DAC for outputting a stable current, said current-steering DAC being provided with a first output end and a second output end, wherein said first output end is electrically connected to said light emitting diode; and
a resistor being electrically connected to said second output end of said current-steering DAC;
wherein said current-steering DAC comprises:
a plurality of current-steering units, each of the said current-steering units comprising a current source and a switching circuit, wherein a first end of said switching circuit is electrically connected to said current source, a second end and a third end of said switching circuit are electrically connected to said first output end and said second output end, respectively, and said switching circuit is controlled by a switching signal to selectively connect one of said second end and said third end to said first end.

9. The LED circuit of claim 8, wherein one end of said resistor and one end of said light emitting diode are electrically connected to a system voltage, and the other end of said light emitting diode and the other end of said resistor are electrically connected to said first output end and said second output end, respectively.

10. The LED circuit of claim 9, wherein said switching signal comprises a first control signal and a second control signal, said second control signal is a reverse signal of said first control signal, said switching circuit comprises a first transistor and a second transistor, a drain of said first transistor and a drain of said second transistor are electrically connected to said second end and said third end, respectively, a source of said first transistor and a source of said second transistor are electrically connected to said first end, and a gate of said first transistor and a gate of said second transistor receive said first control signal and said second control signal, respectively.
